(19) United States
(12) Patent Application Publication
(10) Pub. No.: US 2025/0142752 A1
(43) Pub. Date: May 1, 2025

(54) COVER WINDOW, DISPLAY DEVICE COMPRISING THE SAME AND MANUFACTURING METHOD THEREOF

(71) Applicant: Samsung Display Co., LTD., Yongin-si (KR)

(72) Inventor: Gyeong Sang PARK, Yongin-si (KR)

(73) Assignee: Samsung Display Co., LTD., Yongin-si (KR)

(21) Appl. No.: 18/669,756

(22) Filed: May 21, 2024

(30) Foreign Application Priority Data
Oct. 26, 2023 (KR) 10-2023-0144678

(51) Int. Cl. H05K 5/03; G06F 1/16

(52) U.S. Cl. CPC H05K 5/03; G06F 1/1656

(57) ABSTRACT

A cover window according to an embodiment includes a base layer, and a first sub-opaque layer disposed on the base layer, and the first sub-opaque layer includes additives having magnetic properties.

### CROSS-REFERENCE TO RELATED APPLICATION(S)

This application claims priority to and benefits of Korean Patent Application No. 10-2023-0144678 under 35 U.S.C. § 119 filed at the Korean Intellectual Property Office on Oct. 26, 2023, the entire contents of which are incorporated herein by reference.

### BACKGROUND

### 1. Technical Field

The disclosure relates to a cover window, a display device including the cover window, and a method of manufacturing the cover window.

### 2. Description of the Related Art

A cover window may be disposed on the front of a display panel, such as a liquid crystal display panel, a plasma display panel, or an organic light emitting display panel, to protect the display panel.

The cover window may be attached and fixed to the outer surface of the display panel so that the user can identify the user's input or the output of the device from the outside.

The cover window may be placed on the external surface of the device to influence the design of the device.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a cover window with improved adhesion to an adhesive layer, a display device including the cover window, and a method of manufacturing the cover window.

A cover window according to an embodiment may include a base layer; and a sub-opaque layer disposed on the base layer, wherein the sub-opaque layer may include a plurality of additives having magnetic properties.

The plurality of additives may include at least one of Fe, Al, FeO, and Fe₂O₃.

The plurality of additives may have a core-shell structure.

The core-shell structure may include a core including at least one of SiO₂ and BaSO₄, and the core-shell structure may include a shell including aluminum.

The plurality of additives may be included in the sub-opaque layer in an amount in a range of about 5 wt % to about 15 wt %.

The plurality of additives may be disposed adjacent to a surface of the sub-opaque layer.

The roughness of the surface of the sub-opaque layer may be in a range of about 0.4 micrometers to about 0.7 micrometers.

A display device according to an embodiment may include a display layer disposed on a substrate; and a cover window disposed on the display layer, wherein the cover window may include a base layer, and a first sub-opaque layer disposed on the base layer, wherein the first sub-opaque layer may include a plurality of additives having magnetic properties.

The plurality of additives may include at least one of Fe, Al, FeO, and Fe₂O₃. The plurality of additives may have a core-shell structure.

The core-shell structure may include a core including at least one of SiO₂ and BaSO₄, and the core-shell structure may include a shell including aluminum.

The plurality of additives may be included in the first sub-opaque layer in an amount in a range of about 5 wt % to about 15 wt %.

The plurality of additives may be disposed adjacent to the surface of the first sub-opaque layer.

The roughness of the surface of the first sub-opaque layer may be in a range of about 0.4 micrometers to about 0.7 micrometers.

The display device may further include an adhesive layer disposed between the display layer and the cover window.

A surface of the first sub-opaque layer may face the adhesive layer.

The cover window may further include a second sub-opaque layer disposed between the first sub-opaque layer and the base layer.

A method of manufacturing a cover window according to an embodiment may include preparing a base layer; applying a material layer containing an additive on the base layer; applying a magnetic force on the material layer, and curing the material layer to provide a first sub-opaque layer.

The additive may have magnetic properties.

In the applying of the magnetic force, the additive may move adjacent to the surface of the material layer.

According to embodiments, a cover window with a uniform surface roughness of an opaque layer and a method of manufacturing the cover window can be provided.

Accordingly, the adhesive strength of the opaque layer and the adhesive layer is uniformly provided, thereby providing a display device with improved reliability.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view of a display device according to an embodiment.

FIG. 2 is an exploded perspective view of a display device according to an embodiment.

FIG. 3 is a schematic cross-sectional view of a display device according to an embodiment.

FIG. 4 is a schematic cross-sectional view of a cover window according to an embodiment.

FIG. 5 and FIG. 6 are schematic diagrams of a method of manufacturing a cover window according to an embodiment.

### DETAILED DESCRIPTION OF THE EMBODIMENTS

Hereinafter, with reference to the attached drawings, various embodiments of the disclosure will be described in detail so that those skilled in the art can readily implement the disclosure.

The disclosure may be implemented in many different forms and is not limited to the embodiments described herein.

In order to clearly explain the disclosure, parts that are not relevant to the description may be omitted, and identical or similar components are assigned the same reference numerals throughout the specification.

The size and thickness of each component shown in the drawings are arbitrarily shown for convenience of explanation, thus, the disclosure is not necessarily limited to that which is shown.

In the drawing, the thickness is enlarged to clearly express various layers and regions.

And in the drawings, for convenience of explanation, the thicknesses of some layers and regions are exaggerated.

Additionally, when a part of a layer, membrane, region or plate is said to be “above” or “on” another part, this includes not only cases where it is “directly above” another part, but also cases where there is another part in between.

Conversely, when a part is said to be “right on top” of another part, it means that there is no other part in between.

In addition, being “above” or “on” a reference part means being disposed above or below the reference part, and does not necessarily mean being disposed “above” or “on” it in the direction opposite to gravity.

In addition, throughout the specification, when a part is said to “include” a certain element, this means that it may further include other elements, rather than excluding other elements, unless specifically stated to the contrary.

In addition, throughout the specification, when reference is made to “on a plane,” this means when the target portion is viewed from above, and when reference is made to “in cross-section,” this means when a cross-section of the target portion is cut vertically and viewed from the side.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be understood that, although the terms first, second, etc., may be used herein to describe various elements, these elements should not be limited by these terms. These terms are only used to distinguish one element from another element. For example, a first element may be referred to as a second element, and similarly, a second element may be referred to as a first element without departing from the scope of the disclosure.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical or electrical connection or coupling.

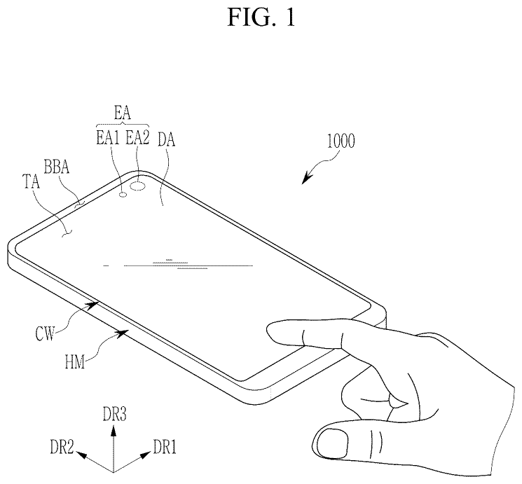

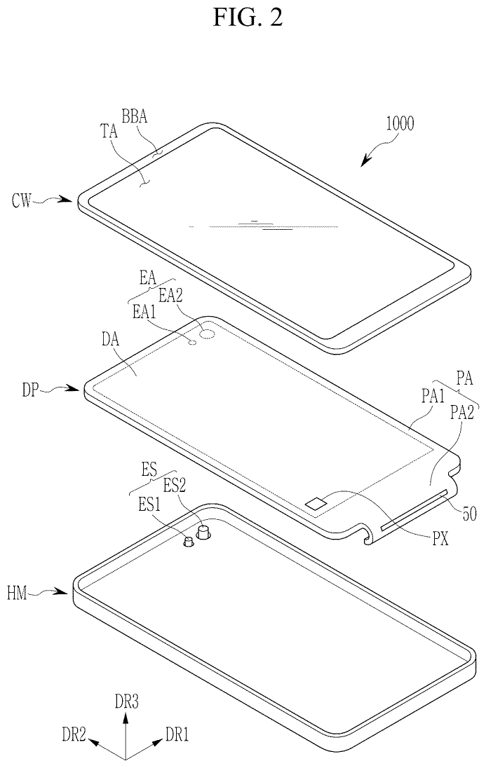

The schematic structure of the display device through FIG. 1 and FIG. 2 will be examined below.

FIG. 1 is a schematic perspective view showing a use state of a display device according to an embodiment, and FIG. 2 is an exploded perspective view of a display device according to an embodiment.

Referring to FIG. 1, a display device 1000 according to an embodiment is a device that displays moving images or still images, and may be used in a mobile phone, a smart phone, a tablet personal computer, or a mobile phone. A display device can be used for various products, such as portable electronic devices such as communication terminals, electronic notebooks, e-books, portable multimedia players (PMP), navigation, ultra mobile PCs (UMPC), as well as televisions, laptops, monitors, billboards, internet of things (IoT), etc.

The display device 1000 according to an embodiment is mounted on a wearable device such as a smart watch, a watch phone, a glasses-type display, and a head-mounted display HMD.

The display device 1000 according to an embodiment includes a dashboard of a car, a center information display CID placed on the center fascia or dashboard of a car, and a room mirror display (a display instead of a side mirror of a car), can be used as entertainment for the back seat of a car, and as a display placed on the back of the front seat.

For convenience of explanation, FIG. 1 shows the display device 1000 being used as a smart phone.

The display device 1000 may display an image in the third direction DR3 on a display surface parallel to each of the first and second directions DR1 and DR2.

The display surface on which the image is displayed may correspond to the front surface of the display device 1000 and the front surface of the cover window CW.

Images may include static images as well as dynamic images.

In this embodiment, the front (or top) and back (or bottom) surfaces of each member are defined based on the direction in which the image is displayed.

The front and back surfaces are opposed to each other in the third direction DR3, and the normal directions of each of the front and back surfaces may be parallel to the third direction DR3.

The separation distance between the front and back surfaces in the third direction DR3 may correspond to the thickness of the display panel in the third direction DR3.

The display device 1000 according to an embodiment may detect a user's input (refer to the hand in FIG. 1) applied from the outside.

The user's input may include various types of external inputs, such as parts of the user's body, light, heat, or pressure.

In an embodiment, the user's input is shown with the user's hand applied to the front.

However, the disclosure is not limited thereto.

The user's input may be provided in various forms, and the display device 1000 may also detect the user's input applied to the side or back of the display device 1000 depending on the structure of the display device 1000.

Referring to FIG. 1 and FIG. 2, the display device 1000 may include a cover window CW, a housing HM, a display panel DP, and an optical element ES.

In an embodiment, the cover window CW and the housing HM may be combined to form the exterior of the display device 1000.

The cover window CW may include an insulating panel.

For example, the cover window CW may be made of glass, plastic, or a combination thereof.

The front of the cover window CW may define the front of the display device 1000.

A transmission area TA may be an optically transparent area.

For example, the transmission area TA may be an area with a visible light transmittance of about 90% or more.

A blocking area BBA may define the shape of the transmission area TA.

The blocking area BBA is adjacent to the transmission area TA and may surround the transmission area TA.

The blocking area BBA may be an area with relatively low light transmittance compared to the transmission area TA.

The blocking area BBA may include an opaque material that blocks light.

The blocking area BBA may have a selectable color.

The blocking area BBA may be defined by an opaque layer (or ink layer) formed by inserting or coloring a transparent base layer defining the transmission area TA.

The display panel DP may include a display pixel PX that displays an image and a driver 50, and the display pixel PX is disposed in the display area DA and a component area EA.

The display panel DP may include a front surface including the display area DA and a non-display area PA.

In an embodiment, the display area DA and the component area EA are areas where images are displayed, including pixels, and at the same time, a touch sensor may be disposed in the upper direction DR3 of the pixels, which can be an area where external input is detected.

The transmission area TA of the cover window CW may at least partially overlap the display area DA and the component area EA of the display panel DP.

For example, the transmission area TA may overlap the front surface of the display area DA and the component area EA, or may overlap at least a portion of the display area DA and the component area EA.

Accordingly, the user can view the image through the transmission area TA or provide external input based on the image.

However, the disclosure is not limited thereto.

For example, the area where an image is displayed and the area where external input is detected may be separated from each other.

The non-display area PA of the display panel DP may at least partially overlap the blocking area BBA of the cover window CW.

The non-display area PA may be an area covered by the blocking area BBA.

The non-display area PA is adjacent to the display area DA and may surround the display area DA.

An image is not displayed in the non-display area PA, and a driving circuit or driving wiring for driving the display area DA may be disposed.

The non-display area PA may include a first non-display area PA1 disposed outside the display area DA and a second non-display area PA2 including the driver 50, connection wiring, and a bending area.

In the embodiment of FIG. 2, the first non-display area PA1 is disposed on the third side of the display area DA, and the second non-display area PA2 is disposed on the remaining side of the display area DA.

A portion of the non-display area PA of the display panel DP may be curved.

At this time, part of the non-display area PA is directed toward the rear of the display device 1000, so that the blocking area BBA visible on the front of the display device 1000 can be reduced, and in FIG. 2, the second non-display area PA2 can be bent and placed on the back of the display area DA and assembled.

For example, the component area EA of the display panel DP may include a first component area EA1 and a second component area EA2.

The first component area EA1 and the second component area EA2 may be at least partially surrounded by the display area DA.

The first component area EA1 and the second component area EA2 are shown spaced apart from each other, but are not limited to this and may be at least partially connected.

The first component area EA1 and the second component area EA2 may be areas where an optical element (see ES in FIG. 2; hereinafter also referred to as a component) that uses infrared rays, visible rays, or sound is disposed.

The display area (DA; hereinafter also referred to as the main display area) and the component area EA are formed with a plurality of light emitting diodes and a plurality of pixel circuit units (or pixel circuit parts) that generate and transmit light emission current to each of the plurality of light emitting diodes.

Here, one light emitting diode and one pixel circuit part are called a pixel PX.

One pixel circuit unit and one light emitting diode may be formed in a one-to-one ratio in the display area DA and the component area EA.

The first component area EA1 may include a permeable part through which light and/or sound can pass, and a display layer containing multiple pixels.

The transmission portion is disposed between adjacent pixels and is composed of a layer through which light and/or sound can pass.

The transmission portion may be disposed between adjacent pixels, and depending on the embodiment, a layer that does not transmit light, such as a light blocking member, may overlap the first component area EA1.

The number of pixels (hereinafter referred to as resolution) per unit area of the pixels (hereinafter referred to as normal pixels) included in the display area DA and the pixels included in the first component area EA1 (hereinafter referred to as first component pixels) the number of pixels per unit area may be the same.

The second component area EA2 may include an area composed of a transparent layer so that light can pass through (hereinafter also referred to as a light transmission area), and the light transmission area does not have a conductive layer or a semiconductor layer and may include a light blocking material, a layer—for example, a pixel defining layer and/or a light blocking member—may have a structure that does not block light by including an opening that overlaps a position corresponding to the second component area EA2.

The number of pixels per unit area of the pixels included in the second component area EA2 (hereinafter also referred to as second component pixels) may be smaller than the number of pixels per unit area of the normal pixels included in the display area DA.

As a result, the resolution of the second component pixel may be lower than that of a normal pixel.

The driver 50 may be positioned on the second non-display area PA2, on the bending portion, or on one side or a side of the bending portion.

The driving unit 50 may be provided in the form of a chip.

The driver 50 is electrically connected to the display area DA and the component area EA, and can transmit electrical signals to pixels in the display area DA and the component area EA.

For example, the driver 50 may provide data signals to the pixels PX arranged or disposed in the display area DA.

By way of example, the driver 50 may include a touch driving circuit and may be electrically connected to a touch sensor disposed in the display area DA and/or the component area EA.

The driver 50 may include various circuits in addition to the above-described circuits or may be designed to provide various electrical signals to the display area DA.

The display device 1000 may have a pad part disposed at the end of the second non-display area PA2, and the pad part can be electrically connected to a flexible printed circuit board FPCB that may include a driving chip.

Here, the driving chip disposed on the flexible printed circuit board may include various driving circuits for driving the display device 1000 or a connector for power supply purposes.

Depending on the embodiment, a rigid printed circuit board (PCB) may be used instead of a flexible printed circuit board.

The optical element ES may be disposed below the display panel DP.

The optical element ES may include a first optical element ES1 overlapping the first component area EA1 and a second optical element ES2 overlapping the second component area EA2.

The first optical element ES1 may use infrared rays, and in this case, a layer that does not transmit light, such as a light blocking member, may overlap the first component area EA1.

The first optical element ES1 may be an electronic element that uses light or sound.

For example, the first optical element ES1 may be a sensor that receives and uses light such as an infrared sensor, a sensor that outputs and detects light or sound to measure distance or recognize a fingerprint, etc., a small lamp that outputs light, or a speaker that outputs sound, etc.

Of course, in the case of electronic elements that use light, light of various wavelength bands, such as visible light, infrared light, and ultraviolet light, can be used.

The second optical element ES2 is at least one of a camera, an IR camera, a dot projector, an IR illuminator, and a time-of-flight sensor.

The housing HM may be combined with the cover window CW.

The cover window CW may be placed on the front of the housing HM.

The housing HM can be combined with the cover window CW to provide a selectable accommodation space. The display panel DP and the optical element ES may be accommodated in a selectable accommodation space provided between the housing HM and the cover window CW.

The housing HM may include a material with relatively high rigidity.

For example, the housing HM may include a plurality of frames and/or plates made of glass, plastic, or metal, or a combination thereof.

The housing HM can stably protect the components of the display device 1000 accommodated in the internal space from external shock.

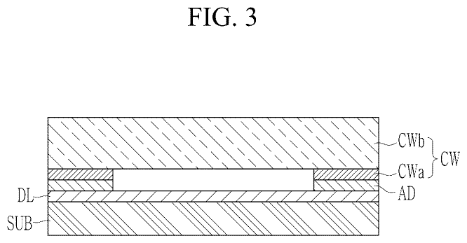

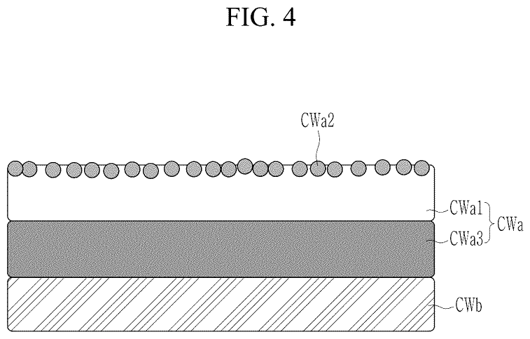

Hereinafter, a cover window and a display device including the same according to an embodiment will be described with reference to FIG. 3 and FIG. 4. FIG. 3 is a schematic cross-sectional view of a display device according to an embodiment, and FIG. 4 is a schematic cross-sectional view of a cover window according to an embodiment.

Referring to FIG. 3, a display panel according to an embodiment may include a substrate SUB and a display layer DL disposed on the substrate SUB.

As described above, the display layer DL may include a plurality of light emitting diodes and a plurality of pixel circuit units that generate and transmit light emission current to each of the plurality of light emitting diodes.

A cover window CW may be disposed on top of the display layer DL.

The cover window CW can protect the top surface of the display layer DL.

The cover window CW may include a base layer CWb and an opaque layer CWa.

In an embodiment, the base layer CWb may be made of a transparent material.

At this time, the base layer CWb may include glass, transparent synthetic resin, etc.

The base layer CWb may include at least one layer.

The opaque layer Cwa may be disposed at the edge of the base layer CWb.

The opaque layer Cwa can block light.

The opaque layer Cwa may include a pattern that can be shown to the user in case that the image is not displayed.

The opaque layer Cwa may define the blocking area BBA of the cover window CW described in FIG. 1.

An adhesive layer AD may be positioned between the cover window CW and the display layer DL.

The cover window CW may be coupled or connected to the display layer DL by an adhesive layer AD.

The adhesive layer AD may be a pressure-sensitive adhesive PSA, an optically clear adhesive OCA, or a glue that functions as an adhesive member.

Briefly explaining the stacked structure of the display panel, the display panel may include a display layer DL and a touch sensing unit (not shown) disposed on the display layer DL.

The display layer DL may include a driving device layer, a light emitting device layer, and an encapsulation layer disposed on the substrate SUB.

The substrate SUB may be a base substrate or a base member.

The substrate SUB may be a flexible substrate containing a polymer resin such as polyimide, polyamide, or polyethylene terephthalate.

The driving element layer may be disposed on the substrate SUB.

The driving element layer may include transistors and capacitors that constitute pixel circuit units that output driving currents to light emitting devices.

The driving element layer may include gate lines, data lines, power lines, gate control lines, fan-out lines connecting the display driver and the data lines, lead lines connecting the display driver and the display pads, etc.

The driving element layer may include transistors and capacitors constituting the gate driver, and gate control lines.

The driving element layer may include conductive layers, semiconductor layers, and insulating layers, and may form and insulate transistors, capacitors, and signal lines by a combination thereof.

The light emitting device layer may be disposed on the driving device layer, and may include light emitting devices and corresponding light emitting regions.

The light emitting device layer may include a pixel defining layer having openings defining light emitting areas.

The encapsulation layer (also referred to as a thin film encapsulation layer) may cover the top and side surfaces of the light emitting device layer and prevent moisture or oxygen from penetrating into the light emitting device layer from the outside.

The encapsulation layer may include one or more inorganic layers and one or more organic layers.

The touch sensing unit may be disposed on the encapsulation layer and may include sensing electrodes.

The sensing electrodes may sense the user's touch using a mutual capacitor method and/or a magnetic capacitor method.

Hereinafter, the cover window according to an embodiment will be described in more detail by incorporating FIG. 3 and FIG. 4.

As described above, the cover window CW according to an embodiment may include a base layer CWb and an opaque layer Cwa disposed on the base layer CWb.

The opaque layer Cwa may be disposed between the base layer CWb and the display layer DL.

The opaque layer Cwa may be adhered to the adhesive layer AD in order to be coupled or connected with the display layer DL.

Referring to FIG. 4, the opaque layer Cwa according to an embodiment may include a first sub-opaque layer Cwa1 and a second sub-opaque layer Cwa3.

The first sub-opaque layer Cwa1 may be in contact with the adhesive layer AD and may be coupled or connected with the adhesive layer AD.

The second sub-opaque layer Cwa3 may be disposed between the first sub-opaque layer Cwa1 and the base layer CWb.

The first sub-opaque layer Cwa1 according to an embodiment may include a plurality of additives Cwa2.

The most of the plurality of additives Cwa2 may be disposed on a side of the first sub-opaque layer Cwa1.

A plurality of additives Cwa2 may be disposed on a side of the first sub-opaque layer Cwa1 facing the adhesive layer AD.

The surface of the first sub-opaque layer Cwa1 may have irregularities due to the plurality of additives Cwa2.

The surface of the first sub-opaque layer Cwa1 may have a selectable roughness, and through this, the adhesive force between the first sub-opaque layer Cwa1 and the adhesive layer AD may be strengthened.

The plurality of additives Cwa2 may be magnetic materials and, for example, may include at least one of Fe, Al, FeO, and Fe₂O₃.

By way of example, the plurality of additives Cwa2 may have a core-shell structure.

The core may include at least one of SiO₂ and BaSO₄ and the shell may be in the form of coating the core with aluminum (Al) to provide magnetic properties.

The diameter of the additive Cwa2 may be several nanometers to several micrometers for example, in a range of about 1 micrometer to about 10 micrometers.

The plurality of additives CWa2 may be included in the first sub-opaque layer CWa1 in an amount in a range of about 5 wt % to about 15 wt %, for example, in a range of about 8 wt % to about 12 wt %, for example, in a range of about 9 wt %. % to about 11 wt %, or, for example, about 10 wt %.

As the content of the additive CWa2 included in the first sub-opaque layer CWa1 increases, the roughness of the surface of the first sub-opaque layer CWa1 may increase.

In case that the additive CWa2 is included at less than about 5 wt %, it may be difficult to provide a selectable roughness of the first sub-opaque layer CWa1 for stable bonding with the adhesive layer AD.

If the additive CWa2 is included in an amount exceeding about 15 wt %, dispersibility and agitation in the first sub-opaque layer CWa1 are reduced, and appearance defects such as bubbles or stains may occur.

The roughness of the surface of the first sub-opaque layer CWa1 facing the adhesive layer AD may be in a range of about 0.4 micrometers to about 0.7 micrometers—for example, in a range of about 0.46 to about 0.6 micrometers.

For example, the adhesive force of the surface of the first sub-opaque layer CWa1 facing the adhesive layer AD may be in a range of about 490 N to about 540 N.

A plurality of additives CWa2 are uniformly disposed on the surface of the first sub-opaque layer CWa1, thereby providing the roughness as described above.

According to this, the adhesive layer AD according to an embodiment may penetrate the gaps between the plurality of additives CWa2 included in the first sub-opaque layer CWa1 to strengthen the adhesive force.

In addition to the above additives, the first sub-opaque layer CWa1 may further include a range of about 30 wt % to about 50 wt % of resin, a range of about 5 wt % to about 50 wt % of pigment, and a range of about 20 wt % to about 30 wt % of solvent.

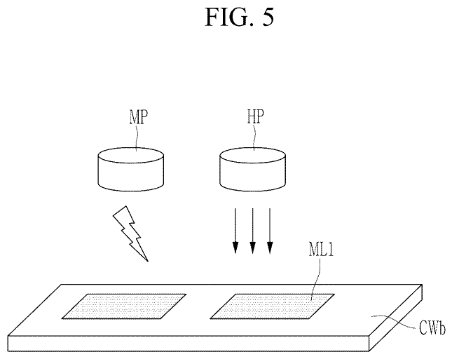

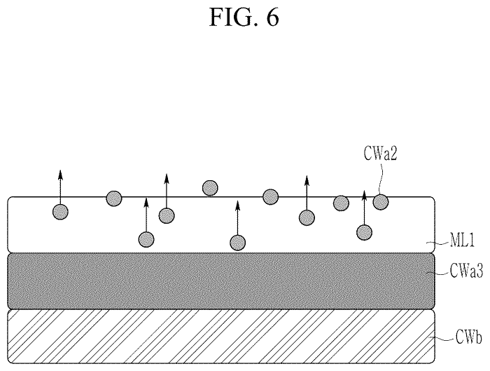

Hereinafter, a method of manufacturing a cover window according to an embodiment will be described with reference to FIG. 5 and FIG. 6.

FIG. 5 and FIG. 6 are diagrams of a method of manufacturing a cover window according to an embodiment.

Description of content that is the same as the above-described content will be omitted.

First, referring to FIG. 5, after forming the second sub-opaque layer (not shown) on the base layer CWb, the first material layer ML1 is formed on the second sub-opaque layer to form the first sub-opaque layer.

The first material forming the first material layer ML1 may include a range of about 30 wt % to about 50 wt % of resin, a range of about 5 wt % to about 50 wt % of pigment, a range of about 20 wt % to about 30 wt % of solvent, and a range of about 5 wt % to about 15 wt % of additives.

After applying the first material layer ML1 to the second sub-opaque layer (not shown), magnetic force MP is provided to the first material layer ML1.

As shown in FIG. 6, as magnetic force is provided to the first material layer ML1, the additive CWa2 dispersed in the first material and having magnetic properties may move to the surface of the first material layer ML1.

By performing a heat-curing process HP on the first material layer ML1, as shown in FIG. 4, the first sub-opaque layer CWa1, where multiple additives CWa2 are bonded with the adhesive layer, can be formed.

A plurality of additives CWa2 are uniformly disposed on the surface of the first sub-sub opaque layer CWa1, thereby providing the surface roughness as described above.

According to this, the adhesive layer AD according to an embodiment may penetrate the gaps between the plurality of additives CWa2 included in the first sub-opaque layer CWa1 to strengthen the adhesive force.

Referring to Table 1 below, it was confirmed that as the content of the additive contained in the first sub-opaque layer increased, the roughness and adhesion of the surface of the first sub-opaque layer increased.

TABLE 1

| content of additives | 0 wt % | 5 wt % | 10 wt % |
|---|---|---|---|
| roughness (μm) | 0.233 | 0.458 | 0.602 |
| adhesion (N) | 456.3 | 498.2 | 526.8 |

The cover window according to an embodiment may include an additive that is uniformly disposed on the surface of the opaque layer through magnet force, and through this, adhesion with the adhesive layer is improved, thereby providing a display device with improved reliability.

Although embodiments of the disclosure have been described in detail above, the scope of the disclosure is not limited thereto, and various modifications and improvements made by those skilled in the art using concepts of the disclosure and defined in the following claims are also possible.

What is claimed is:

1. A cover window, comprising:
a base layer; and
a sub-opaque layer disposed on the base layer; and
the sub-opaque layer includes a plurality of additives having magnetic properties.

2. The cover window of claim 1, wherein the plurality of additives include at least one of Fe, Al, FeO, and Fe₂O₃.

3. The cover window of claim 1, wherein the plurality of additives have a core-shell structure.

4. The cover window of claim 3, wherein
the core-shell structure includes a core including at least one of SiO₂ and BaSO₄, and
the core-shell structure includes a shell including aluminum.

5. The cover window of claim 1, wherein the plurality of additives are included in the sub-opaque layer in an amount in a range of about 5 wt % to about 15 wt %.

6. The cover window of claim 1, wherein the plurality of additives are disposed adjacent to a surface of the sub-opaque layer.

7. The cover window of claim 1, wherein a surface of the sub-opaque layer has a roughness in a range of about 0.4 micrometers to about 0.7 micrometers.

8. A display device, comprising:
a display layer disposed on a substrate; and
a cover window disposed on the display layer, wherein
the cover window comprises:
a base layer; and
a first sub-opaque layer disposed on the base layer, and
the first sub-opaque layer includes a plurality of additives having magnetic properties.

9. The display device of claim 8, wherein the plurality of additives include at least one of Fe, Al, FeO, and Fe₂O₃.

10. The display device of claim 8, wherein the plurality of additives have a core-shell structure.

11. The display device of claim 10, wherein
the core-shell structure includes a core including at least one of SiO₂ and BaSO₄, and
the core-shell structure includes a shell including aluminum.

12. The display device of claim 8, wherein the plurality of additives are included in the first sub-opaque layer in an amount in a range of about 5 wt % to about 15 wt %.

13. The display device of claim 8, wherein the plurality of additives are disposed adjacent to a surface of the first sub-opaque layer.

14. The display device of claim 13, wherein the surface of the first sub-opaque layer has a roughness in a range of about 0.4 micrometers to about 0.7 micrometers.

15. The display device of claim 14, further comprising:
an adhesive layer disposed between the display layer and the cover window.

16. The display device of claim 15, wherein the surface of the first sub-opaque layer faces the adhesive layer.

17. The display device of claim 8, wherein the cover window further includes a second sub-opaque layer disposed between the first sub-opaque layer and the base layer.

18. A method of manufacturing a cover window, comprising:
preparing a base layer;
applying a material layer containing an additive on the base layer;
applying a magnetic force on the material layer; and
curing the material layer to provide a sub-opaque layer.

19. The method of manufacturing a cover window of claim 18, wherein the additive has magnetic properties.

20. The method of manufacturing a cover window of claim 18, wherein the applying of the magnetic force, the additive moves adjacent to a surface of the material layer.
